(19) United States
(12) Patent Application Publication
(10) Pub. No.: US 2003/0039293 A1
(43) Pub. Date: Feb. 27, 2003

(54) Eye safe monolithic compact laser

(76) Inventor: Richard Scheps, Rancho Santa Fe, CA (US)

Correspondence Address: COMMANDING OFFICER, OFFICE OF PATENT COUNSEL CODE D0012, SPAWARSYSCEN SAN DIEGO, 53510 SILVERGATE AVENUE, ROOM 103, SAN DIEGO, CA, 92152-5765, US

(21) Appl. No.: 09/934,661

(22) Filed: Aug. 22, 2001

(51) Int. Cl. H01S 3/11; H01S 3/10; H01S 5/00; H01S 3/09

(52) U.S. Cl. 372/69; 372/21; 372/22; 372/10

(57) ABSTRACT

The present invention has applications in which the human eye may be exposed to lasers used in a variety of devices for pointing, imaging, industrial cutting and drilling, and for medical procedures. In one aspect of the invention, laser energy is transformed into light having a wavelength that is eye-safe. In a specific embodiment, an eye-safe laser includes a laser for coupling to a source of pump energy to generate laser energy and a Raman shifting crystal for transforming the laser energy into eye-safe light. In one such embodiment, the laser energy has a wavelength of about 1.3 microns and the eye-safe light has a wavelength of about 1.5 microns.

### BACKGROUND OF THE INVENTION

The present invention relates generally to generating a laser beam having a wavelength that is safe for the human eye. More specifically, but without limitation thereto, the present invention relates to a laser that is eye-safe.

### SUMMARY OF THE INVENTION

The present invention has applications in which the human eye may be exposed to lasers used in a variety of devices for pointing, imaging, industrial cutting and drilling, and for medical procedures.

In one aspect of the invention, laser energy is transformed into light having a wavelength that is eye-safe. In a specific embodiment, an eye-safe laser includes a laser for coupling to a source of pump energy to generate laser energy and a Raman shifting crystal for transforming the laser energy into eye-safe light. In one such embodiment, the laser energy has a wavelength of about 1.3 microns and the eye-safe light has a wavelength of about 1.5 microns.

In another aspect of the invention, the eye-safe laser includes the source of pump energy. The source of pump energy may be a laser diode or a laser diode array.

The Raman shifting crystal may comprise BaNO₃ or Kgd(WO₄)₂. There may also be a reflective coating on an inside end face of the Raman shifting crystal that is highly transmissive of the laser energy and is highly reflective of the eye-safe light. In another embodiment, there may be a reflective coating on an outside end face of the Raman shifting crystal that is highly reflective of the laser energy and is highly transmissive of the eye-safe light.

In a further aspect of the invention, the laser may include an input coupler for coupling to a source of pump energy; a laser gain element coupled to the input coupler for generating laser energy from the pump energy; and an output coupler coupled to the laser gain element.

The eye-safe laser may be constructed as a monolithic solid state laser. The input coupler, the laser gain element, the output coupler, and the Raman shifting crystal may be joined by diffusion bonding, gluing, and/or optical contacting by mechanical means.

In another aspect of the invention, the eye-safe laser includes a passive Q-switch coupled to the laser gain element for increasing peak power output. The input coupler, the laser gain element, the passive Q-switch, the output coupler, and the Raman shifting crystal may be joined by diffusion bonding, gluing, and/or optical contacting by mechanical means. The passive Q-switch may comprise a passive Q-switch material, and the material may be V³⁺:YAG or Nd²⁺:SrF₂. In a further aspect of the invention, the output coupler comprises a reflective coating between the Q-switch and the Raman shifting crystal that is partially reflective of the laser energy and is highly reflective of the pump energy.

The eye-safe laser may include a focusing lens for focusing pump energy on the laser gain element, and the input coupler may comprise a reflective coating on an end face of the laser gain element between the laser gain element and the pump energy source that is highly transmissive of the pump energy and highly reflective of the laser energy. The output coupler may comprise a reflective coating between the laser gain element and the Raman shifting crystal that is partially reflective of the laser energy and highly reflective of the pump energy.

The laser gain element may comprise an Nd³⁺:YAlO₃ crystal having a laser wavelength of about 1.3 microns.

### BRIEF DESCRIPTION OF THE DRAWINGS

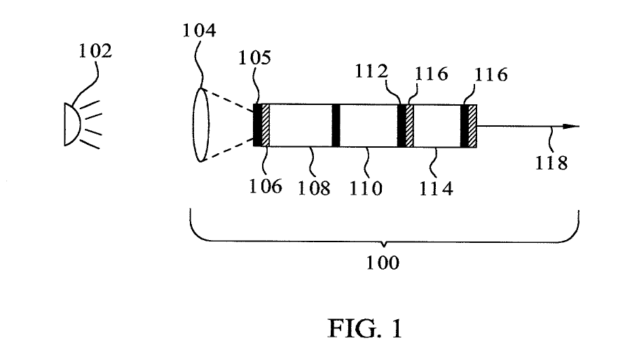

The above and other aspects, features and advantages of the present invention will be more apparent from the following more specific description thereof, presented in conjunction with the following drawings wherein FIG. 1 is a diagram of an eye-safe laser according to an embodiment of the present invention.

### DESCRIPTION OF SOME EMBODIMENTS

Typically, lasers used for pointing, imaging, industrial cutting and drilling, and for medical procedures emit energy having a wavelength that may result in damage to the eye if proper protective measures are not taken, or if accidental exposure of the eye to the laser beam should occur. This problem is addressed in the present invention by transforming the wavelength of the laser to a wavelength that will not result in damage to the eye. This may be achieved by directing the laser energy into a Raman shifting crystal. The Raman shifting crystal absorbs the laser energy having the dangerous wavelength and emits laser energy having a wavelength that is safe for the eye.

The present invention has applications in which the human eye may be exposed to lasers used in a variety of devices for pointing, imaging, industrial cutting and drilling, and for medical procedures. In one aspect of the invention, laser energy is transformed into light having a wavelength that is eye-safe. In a specific embodiment, an eye-safe laser includes a laser for coupling to a source of pump energy to generate laser energy and a Raman shifting crystal for transforming the laser energy into eye-safe light. In one such embodiment, the laser energy has a wavelength of about 1.3 microns and the eye-safe light has a wavelength of about 1.5 microns.

FIG. 1 is a diagram of an eye-safe laser 100 according to an embodiment of the present invention. Shown in FIG. 1 are a pump energy source 102, a focusing lens 104, a reflective coating 105, an input coupler 106, a laser gain element 108, a passive Q-switch 110, an output coupler 112, a Raman shifting crystal 114, anti-reflective coatings 116 and 117, and an output beam 118 of eye-safe light.

The pump energy source 102 may be, for example, a laser diode or a laser diode array. Pump energy from the pump energy source 102 is focused by the focusing lens 104 through the input coupler 106 on the laser gain element 108. The input coupler 106 may include, for example, the reflective coating 105 on an end face of the laser gain element 108 adjacent to the focusing lens 104. The input coupler 106 is preferably highly transmissive at the wavelength of the pump energy and is highly reflective at the laser wavelength of the laser energy generated by the laser gain element 108.

The laser gain element 108 may be, for example, a neodymium-doped crystal such as Nd³⁺:YAlO₃ that is well known in the art for generating laser energy having a laser wavelength of about 1.3 microns. The laser gain element 108 may be operated more efficiently at shorter wavelengths, but a higher order Stokes shift would be required of the Raman shifting crystal 114 to generate light at an eye-safe wavelength of about 1.5 microns.

The peak optical power output generated by the laser gain element 108 may be increased by including the passive Q-switch 110. The passive Q-switch 110 may be, for example, a crystal made of a passive Q-switch material such as V³⁺:YAG or Nd²⁺:SrF₂. The passive Q-switch is operated according to well known techniques at the laser wavelength and acts as a shutter to transmit pulses of laser energy about 20 ns in length generated by the laser gain element 108 at a variable frequency from about 1 Hz to tens of kiloHerz.

The output coupler 112 may be, for example, a coated mirror adjacent to the passive Q-switch 110, if included, or between the laser gain element 108 and the Raman shifting crystal 114 if the passive Q-switch 110 is not included. The output coupler 112 is preferably partially reflective, for example, 10% to 99% reflective, at the laser wavelength and may also be highly reflective, i.e., 99 percent to 100 percent reflective, at the pump energy wavelength to improve optical efficiency of the laser gain element 108.

The Raman shifting crystal 114 may be made of, for example, BaNO₃ or Kgd(WO₄)₂ which transforms the laser energy having a wavelength of approximately 1.3 microns to eye-safe light having a wavelength of about 1.5 microns. An example of a suitable Raman shifting crystal 114 may be found in “Stimulated Raman Scattering of Laser Radiation in Raman Crystals”, P. G. Zverev, T. T. Basiev, and A. M. Prokhorov, Optical Materials, Vol. 11, pp. 335-352, 1999.

The anti-reflective coatings 116 and 117 may be added to the end faces of the Raman shifting crystal 114. The anti-reflective coating 116 on the inside end face is preferably highly transmissive at the laser wavelength and highly reflective at the wavelength of the eye-safe light. The high reflectivity at the wavelength of the eye-safe light ensures that all of the eye-safe light 118 generated by the Raman shifting crystal 114 is reflected to the right along the beam of eye-safe light 118. The anti-reflective coating 117 on the outside end face is preferably highly reflective at the laser wavelength and highly transmissive at the wavelength of the eye-safe light. The high reflectivity at the laser wavelength ensures that any remaining energy at the laser wavelength is not mixed with the output beam of eye-safe light 118.

The input coupler 106, the laser gain element 108, the passive Q-switch 110, the output coupler 112, the Raman shifting crystal 114, and the anti-reflective coatings 116 and 117 may be diffusion bonded, glued, or optically contacted together by mechanical means according to well known techniques to form a compact, monolithic device for generating a beam of eye-safe light.

While the invention herein disclosed has been described by means of specific embodiments and applications thereof, other modifications, variations, and arrangements of the present invention may be made in accordance with the above teachings other than as specifically described to practice the invention within the spirit and scope defined by the following claims.

What is claimed is:

1. An eye-safe laser comprising:
a laser for coupling to a source of pump energy to generate laser energy; and
a wavelength shifting crystal coupled to the laser for generating eye-safe light from the laser energy.

2. The eye-safe laser of claim 1 wherein the laser energy has a wavelength of about 1.3 microns.

3. The eye-safe laser of claim 1 wherein the eye-safe light has a wavelength of about 1.5 microns.

4. The eye-safe laser of claim 1 further comprising the source of pump energy.

5. The eye-safe laser of claim 4 wherein the source of pump energy comprises a laser diode or a laser diode array.

6. The eye-safe laser of claim 1 wherein the wavelength shifting crystal comprises a Raman shifting crystal

7. The eye-safe laser of claim 6 wherein the Raman shifting crystal comprises BaNO₃ or KGd(WO₄)₂.

8. The eye-safe laser of claim 1 further comprising a reflective coating on an inside end face of the wavelength shifting crystal that is highly transmissive of the laser energy and is highly reflective of the eye-safe light.

9. The eye-safe laser of claim 1 further comprising a reflective coating on an outside end face of the wavelength shifting crystal that is highly reflective of the laser energy and is highly transmissive of the eye-safe light.

10. The eye-safe laser of claim 1 wherein the laser comprises:
an input coupler for coupling to a source of pump energy;
a laser gain element coupled to the input coupler for generating laser energy from the pump energy; and
an output coupler coupled to the laser gain element.

11. The eye-safe laser of claim 10 wherein the input coupler, the laser gain element, the output coupler, and the wavelength shifting crystal are joined by at least one of diffusion bonding, gluing, and optical contacting by mechanical means.

12. The eye-safe laser of claim 10 further comprising a passive Q-switch coupled to the laser gain element for increasing peak power output.

13. The eye-safe laser of claim 12 wherein the input coupler, the laser gain element, the passive Q-switch, the output coupler, and the Wavelength shifting crystal are joined by at least one of diffusion bonding, gluing, and optical contacting by mechanical means.

14. The eye-safe laser of claim 12 wherein the passive Q-switch comprises a passive Q-switch material.

15. The eye-safe laser of claim 13 wherein the passive Q-switch material is V³⁺:YAG or Nd²⁺:SrF₂.

16. The eye-safe laser of claim 12 wherein the output coupler comprises a reflective coating between the Q-switch and the wavelength shifting crystal that is partially reflective of the laser energy and is highly reflective of the pump energy.

17. The eye-safe laser of claim 10 further comprising a focusing lens coupled to the laser diode for focusing pump energy on the laser gain element.

18. The eye-safe laser of claim 10 wherein the input coupler comprises a reflective coating on an end face of the laser gain element between the laser gain element and the pump energy source that is highly transmissive of the pump energy and highly reflective of the laser energy.

19. The eye-safe laser of claim 10 wherein the output coupler comprises a reflective coating between the laser gain element and the Wavelength shifting crystal that is partially reflective of the laser energy and highly reflective of the pump energy.

20. The eye-safe laser of claim 10 wherein the laser gain element comprises an Nd³⁺:YAlO₃ crystal having a laser wavelength of about 1.3 microns.

21. An eye-safe laser comprising:
means for generating laser energy; and
means for transforming the laser energy into eye-safe light.

22. The eye-safe laser of claim 21 wherein the laser energy has a wavelength of about 1.3 microns.

23. The eye-safe laser of claim 21 wherein the eye-safe light has a wavelength of about 1.5 microns.

24. The eye-safe laser of claim 21 wherein the means for generating laser energy comprises:
an input coupler for receiving pump energy;
a laser gain element coupled to the input coupler for generating laser energy from the pump energy; and
an output coupler coupled to the laser gain element.

25. The eye-safe laser of claim 24 further comprising means for generating the pump energy.

26. The eye-safe laser of claim 25 wherein the means for generating the pump energy comprises a laser diode or a laser diode array.

27. The eye-safe laser of claim 24 wherein the input coupler, the laser gain element, the output coupler, and the means for transforming the laser energy into eye-safe light are joined by at least one of diffusion bonding, gluing, and optical contacting by mechanical means.

28. The eye-safe laser of claim 24 further comprising means for increasing peak power output of the laser gain element.

29. The eye-safe laser of claim 28 wherein the means for increasing peak power output comprises a passive Q-switch material.

30. The eye-safe laser of claim 29 wherein the passive Q-switch material is V³⁺:YAG or Nd²⁺:SrF₂.

31. The eye-safe laser of claim 24 further comprising means for focusing the pump energy on the laser gain element.

32. The eye-safe laser of claim 24 wherein the laser gain element comprises an Nd³⁺:YAlO₃ crystal having a laser wavelength of about 1.3 microns.

33. The eye-safe laser of claim 21 wherein the means for transforming comprises BaNO₃ or KGd(WO₄)₂.
